(19) United States
(12) Patent Application Publication
(10) Pub. No.: US 2005/0231926 A1
(43) Pub. Date: Oct. 20, 2005

(54) Wiring board, balun and apparatus using wiring board, and method of manufacturing wiring board

(76) Inventors: Hideyuki Ito, Mizuho-shi (JP); Kenji Endo, Koriyama-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/103,592

(22) Filed: Apr. 12, 2005

(30) Foreign Application Priority Data
Apr. 19, 2004 (JP) 2004-122580

(51) Int. Cl. H05K 1/09; H05K 1/03; H05K 7/06

(52) U.S. Cl. 361/765; 361/779; 174/257; 174/258

(57) ABSTRACT

A wiring board includes an insulating inorganic base, a conductor pattern provided on the base and including silver, a nickel oxide layer provided on the conductor pattern and covering the conductor pattern, and an insulating layer provided on the nickel oxide layer. The conductor pattern includes 5 wt % to 12 wt % of phosphorus. This wiring board is prevented from having migration at the conductor pattern, thus being prevented insulation failure at the conductor pattern.

### FIELD OF THE INVENTION

The present invention relates to a wiring board and a balun including the wiring board used for various electronic apparatuses and communication apparatuses, and to a method of manufacturing the wiring board.

### BACKGROUND OF THE INVENTION

As portable apparatuses, such as portable electronic apparatuses and portable phones recently have been highly functional, electronic components used for the apparatuses is demanded to be small. This provides high density and fine processing of conductor patterns on wiring boards used for these apparatuses, reducing spaces between adjacent conductor patterns.

A conventional wiring board and a method of manufacturing the wiring board disclosed in Japanese Patent Laid-Open Publication No. 58-32492 and H09-237957 will be described below.

FIG. 21 is a sectional view of the conventional wiring board. Conductor patterns 2a and 2b made of silver are provided on surface 1a of inorganic, alumina board 1. Nickel layers 3a and 3b are formed on sides of conductor patterns 2a and 2b, respectively. Insulating layer 4 covers board 1, conductor patterns 2a and 2b, and nickel layers 3a and 3b.

FIG. 22 is a flowchart showing the method of manufacturing the wiring board. Silver paste 12 is printed on board 1 by screen printing (Step 11), and is baked at approximately 850° C. (Step 13), thus providing conductor patterns 2a and 2b. Nickel paste 5 made of nickel powder, epoxy resin as binder, and organic solvent is printed on sides of conductor patterns 2a and 2b (Step 14). Nickel paste 5 is baked at approximately 650° C. (Step 15), thus providing nickel layers 3a and 3b. Paste 17 made of borosilicate lead glass covering conductor patterns 2a and 2b and nickel layers 3a and 3b is printed (Step 16), and is baked (Step 18), thus providing insulating layer 4. At Steps 13, 15, and 18, silver paste 12, nickel paste 5, and glass paste 17 are all baked in the atmospheric ambience.

In the conventional wiring board, nickel paste 5 is baked in the atmospheric ambience at Step 15, hence being oxidized. This causes nickel layers 3a and 3b to have a small strength, possibly having cracks therein, and silver migration may accordingly occur between conductor patterns 2a and 2b, causing insulation failure accordingly.

### SUMMERY OF THE INVENTION

A wiring board includes an insulating inorganic base, a conductor pattern provided on the base and including silver, a nickel oxide layer provided on the conductor pattern and covering the conductor pattern, and an insulating layer provided on the nickel oxide layer. The conductor pattern includes 5 wt % to 12 wt % of phosphorus.

This wiring board is prevented from having migration at the conductor pattern, thus being prevented insulation failure at the conductor pattern.

### BRIEF DESCRIPTION OF THE DRAWINGS

FIG. 1 is a sectional view of a wiring board according to Exemplary Embodiment 1 of the present invention.

FIG. 2 is a flowchart showing a method of manufacturing the wiring board according to Embodiment 1.

FIG. 3 is a flowchart of forming conductor patterns on the wiring board according to Embodiment 1.

FIG. 4 is a sectional view of equipment for manufacturing an intaglio used for manufacturing the wiring board according to Embodiment 1.

FIG. 5 is an enlarged sectional view of an essential portion of the intaglio used for manufacturing the wiring board according to embodiment 1.

FIG. 6 is a sectional view of the intaglio used for manufacturing the wiring board according to Embodiment 1.

FIG. 7 is a sectional view of the intaglio used for manufacturing the wiring board according to Embodiment 1.

FIG. 8 is a sectional view of the intaglio used for manufacturing the wiring board according to Embodiment 1.

FIG. 9 is a sectional view of the intaglio used for manufacturing the wiring board according to Embodiment 1.

FIG. 10 is a sectional view of the intaglio used for manufacturing the wiring board and the wiring board according to Embodiment 1.

FIG. 11 is a sectional view of the wiring board and the intaglio used for manufacturing the wiring board according to Embodiment 1.

FIG. 12 is a sectional view of the wiring board for illustrating the method of manufacturing the wiring board according to Embodiment 1.

FIG. 13 is a sectional view of the wiring board for illustrating the method of manufacturing the wiring board according to Embodiment 1.

FIG. 14 is a sectional view of the wiring board for illustrating the method of manufacturing the wiring board according to Embodiment 1.

FIG. 15 is a sectional view of the wiring board for illustrating the method of manufacturing the wiring board according to Embodiment 1.

FIG. 16 is a sectional view of another wiring board according to Embodiment 1.

FIG. 17 shows hardness characteristics of a nickel oxide layer of the wiring board according to Embodiment 1.

FIG. 18 is a block diagram of an apparatus, a portable phone, according to Exemplary Embodiment 2 of the invention.

FIG. 19 is a circuit diagram of a balun in a receiving system of the portable phone according to Embodiment 2.

FIG. 20 is a circuit diagram of a balun in a transmitting system of the portable phone according to Embodiment 2.

FIG. 21 is a sectional view of a conventional wiring board.

FIG. 22 is a flowchart showing a method of manufacturing the conventional wiring board.

### DETAILED DESCRIPTION OF THE PREFERRED EMBODIMENTS

### Exemplary Embodiment 1

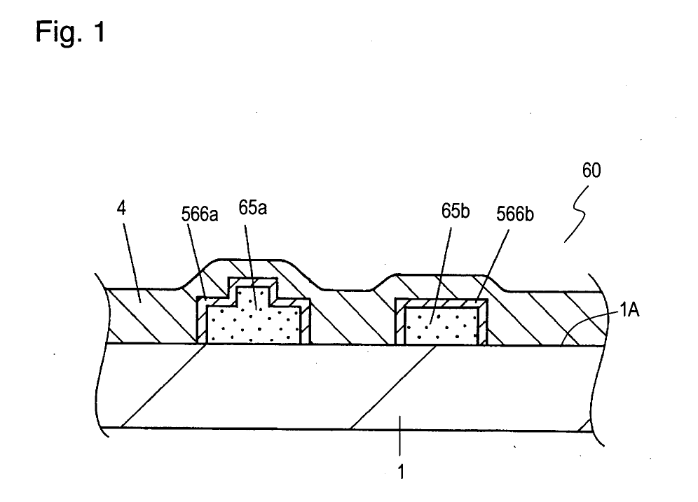

FIG. 1 is a sectional view of wiring board 60 according to Exemplary Embodiment 1 of the present invention. Conductor patterns 65a and 65b containing silver are provided on surface 1A of alumina board 1, an insulating inorganic base. Nickel oxide layers 566a and 566b containing phosphorus are provided on surfaces of conductor patterns 65a and 65b to cover conductor patterns 65a and 65b, respectively. Insulating layer 4 is formed on alumina board 1 and nickel oxide layers 566a and 566b to electrically and physically protect conductor patterns 65a and 65b.

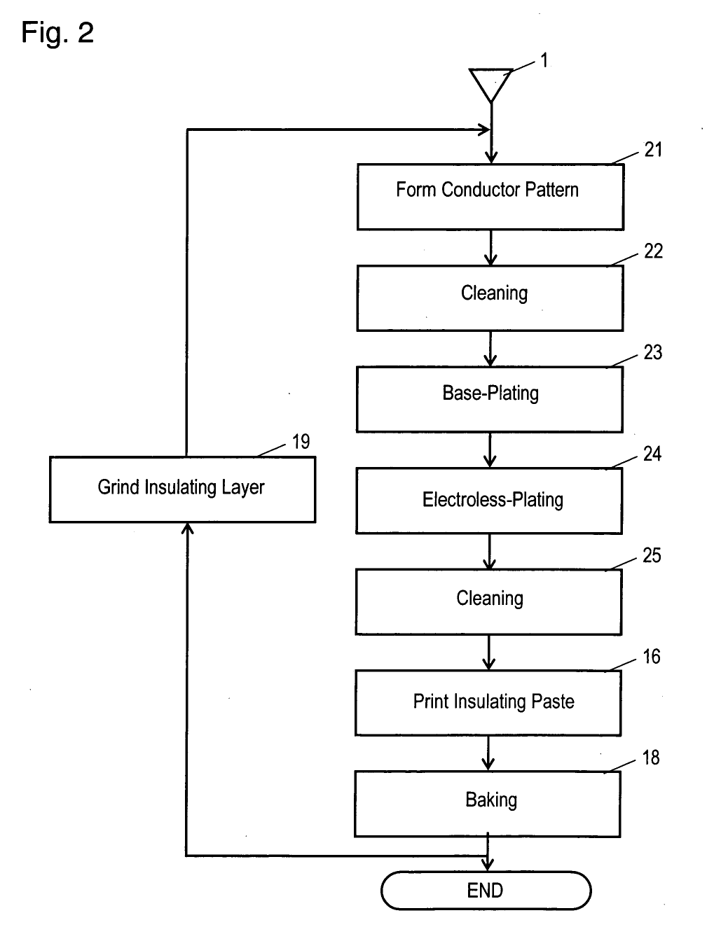

FIG. 2 is a flowchart showing a method of manufacturing wiring board 60 according to Embodiment 1. Conductor patterns 65a and 65b are formed on alumina board 1 (Step 21), and alumina board 1 having conductor patterns 65a and 65b thereon is cleaned (Step 22). Then, a base plating is performed to nickel layers 66a and 66b (Step 23), an electroless plating is performed (Step 24), and alumina board 1 and nickel layers 66a and 66b are cleaned (Step 25). Next, paste 17 made of borosilicate lead glass is printed on alumina board 1 and nickel layers 66a and 66b by screen printing (Step 16), and is baked (Step 18).

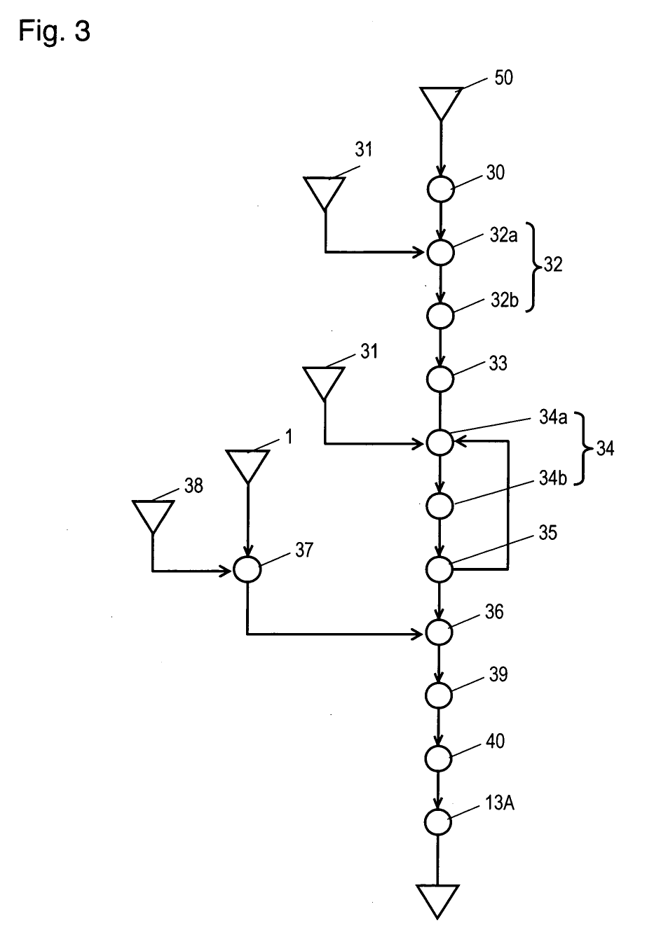

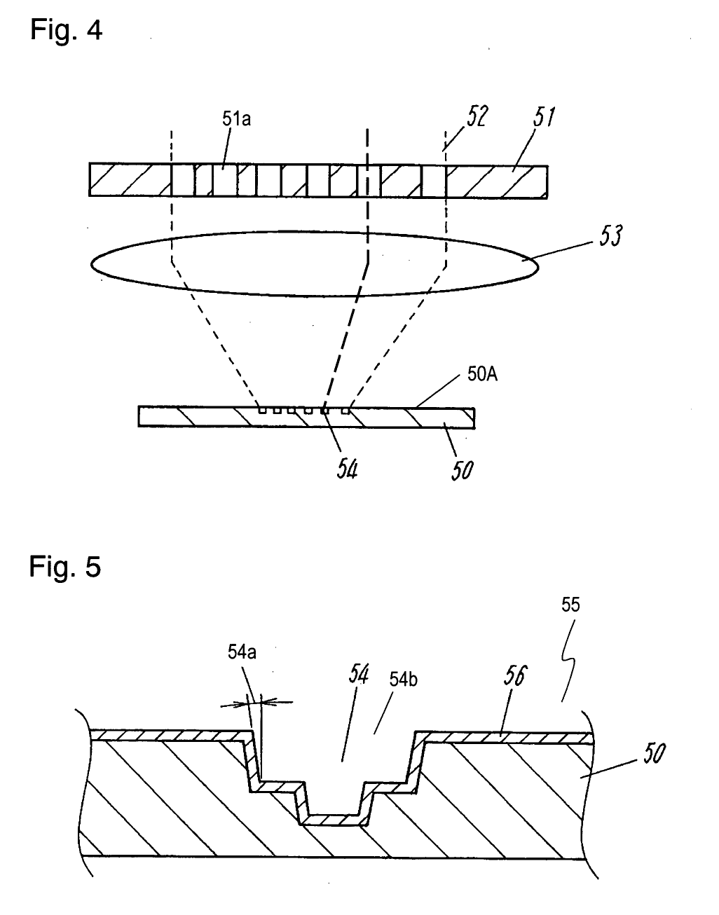

Processes shown in FIG. 2 will be described. FIG. 3 is a flowchart showing a process of forming wiring pattern 65a and 65b in Step 21. FIG. 4 is a sectional view of equipment for manufacturing an intaglio used for forming conductor patterns 65a and 65b. Recess 54 is formed in film 50 by laser processing to provide the intaglio (Step 30). Recess 54 is filled with conductive paste 31 containing silver (Step 32), and the conductive paste 31 is dried (Step 33). After drying conductive paste 31 at Step 33, recess 54 is filled with conductive paste 31 again (Step 34), and then, the filling conductive paste is dried (Step 35).

Adhesive 38 is applied on a surface of board 1 (Step 37), and then, the intaglio having conductive paste 31 produced at Step 35 is placed on the surface of board 1 (Step 36). Board 1 and the intaglio bonded together at Step 36 are heated and pressurized (Step 37). Then, the intaglio is removed off from alumina board 1 (Step 40), and then, alumina board 1 is baked (Step 13A).

Processes of forming conductor patterns 65a and 65b shown in FIG. 3 will be described. As shown in FIG. 4, chrome mask 51 is placed above surface 50A of flexible film 50 made of polyimide and having a thickness of 125 μm. Film 50 is irradiated with excimer laser 52 from above chrome mask 51. Chrome mask 51 has hole 51a therein, and lens 53 is located between chrome mask 51 and film 50. Excimer laser 52 passing through hole 51a of chrome mask 51 through lens 53 provides an image corresponding to hole 51a on surface 50A of film 50, providing recess 54 in surface 50A of film 50.

FIG. 5 is an enlarged sectional view of an essential portion of intaglio 55 formed with equipment shown in FIG. 4. Recess 54 is processed so as to flare toward opening 54b by gradient angle 54a of about 2°. Releasing layer 56 made of fluorine-based releasing agent is formed on surface 50A of film 50 having recess 54 formed therein, providing intaglio 55.

In the process of filling recess 54 of intaglio 55 with conductive paste 31 at Step 32, conductive paste 31 is printed on releasing layer 56 of intaglio 55 by screen printing so as to fill recess 54 (Step 32a), and then, an unnecessary conductive paste overfilling recess 54 is removed (Step 32b).

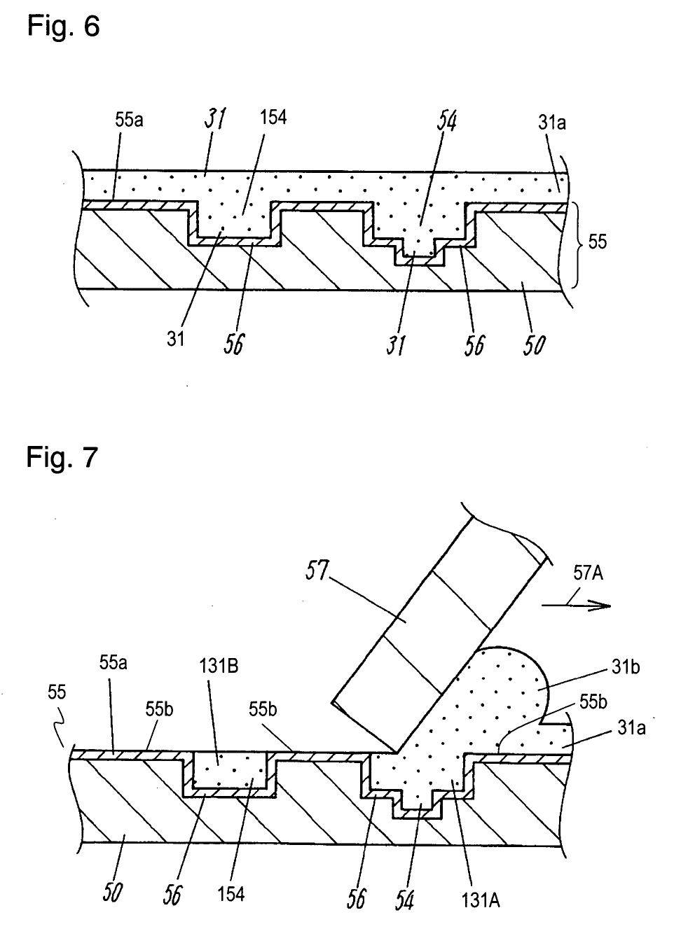

FIG. 6 is a sectional view of intaglio 55 having conductive paste 31 printed thereon at Step 32a. Recess 154 formed simultaneously to recess 54 is formed in intaglio 55. First, a screen (not illustrated) made of stainless-steel having a thickness of 100 μm is placed on surface 55a of intaglio 55, i.e., on a surface of releasing layer 56. A squeegee is moved to print conductive paste 31 on releasing layer 56. This causes conductive paste 31 to fill recesses 54 and 154, thus providing layer 31a of conductive paste 31 having a substantially-uniform thickness of about 100 μm on surface 55a of intaglio 55. The screen has an opening larger than a region including recesses 54 and 154 on surface 55a of intaglio 55, hence allowing conductive paste 31 to fill recesses 54 and 154. Intaglio 55 having conductive paste 31 printed thereon is rotated with a centrifugal separator, and recesses 54 and 154 are filled with conductive paste 31 even into all corners of the recesses, thereby removing bubbles produced in conductive paste 31.

FIG. 7 is a sectional view of intaglio 55 having conductive paste 31 printed thereon at Step 32b. Squeegee 57 moves in direction 57A to scrape surface 55a of intaglio 55, and unnecessary conductive paste 31b on portion 55b of surface 55a where recesses 54 and 154 are not formed is removed, and conductive pastes 131A and 131B fill recesses 54 and 154, respectively, and remain there.

Next, at Step 33, conductive pastes 131A and 131B filling recesses 54 and 154 is dried at a temperature which vaporizes solvent included in the pastes and does not have resin included in the pastes deteriorate. The solvent included in conductive paste 31 may employ alcohols solvent, such as isopropyl alcohol. Conductive paste 31 includes about 60 wt % of silver powder, about 38% of the solvent, and the remaining binder, and is dried preferably at about 150° C. at Step 33.

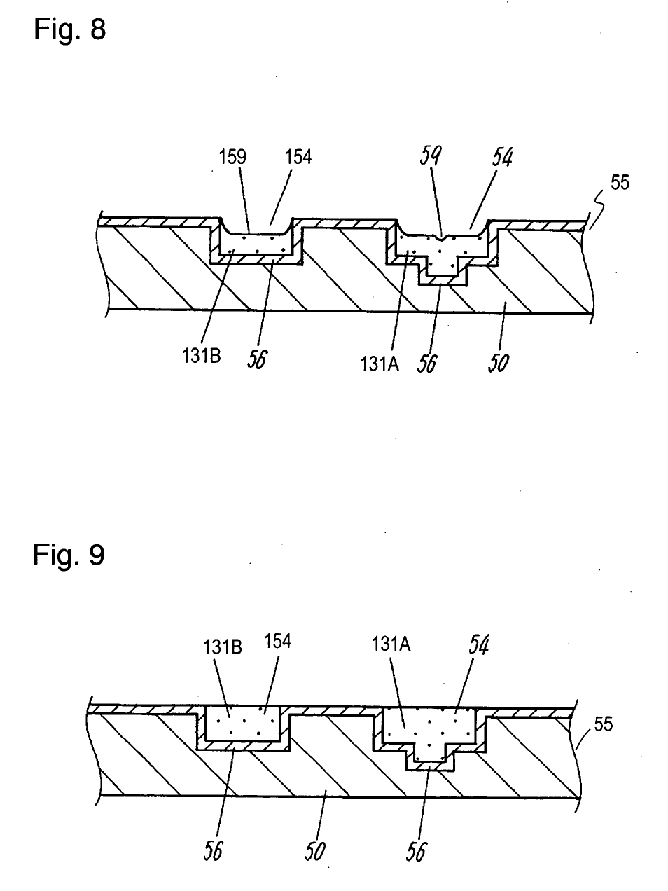

FIG. 8 is a sectional view of intaglio 55 after conductive pastes 131A and 131B dry at Step 33. The solvent is included in conductive paste 31 at 38 wt %, hence decreasing the volumes conductive pastes 131A and 131B according to the vaporization of the solvent due to the drying at Step 33, thus producing recesses 59 and 159, respectively.

Next, at Step 34, recess 59 is again filled with conductive paste 31 to compensate the decreased volumes. Conductive paste 31 is printed on surface 55a of intaglio 55 as shown in FIG. 6 similarly to Step 32a (Step 34a), and then, an unnecessary portion of conductive paste 31a is removed similarly to Step 32b (Step 34b). Conductive pastes 131A and 131B filling recesses 59 and 159 at Step 34b are dried at Step 35. Steps 34 and 35 are repeated until recesses 54 and 154 are substantially fully filled with conductive pastes 131A and 131B, as shown in FIG. 9. According to Embodiment 1, Steps 34 and 35 are executed repetitively for five times to fill recesses 54 and 154 substantially fully with conductive pastes 131A and 131B.

According to Embodiment 1, conductive paste 31 contains about 60 wt % of silver powder as to be printed easily. Increasing the percentage of silver powder content, i.e., deceasing that of the solvent decreases the number of the filling at Step 34 and the drying at Step 35.

At Step 37, alumina board 1 is immersed in mixture solution of polyvinyl butyral (PVB) resin as adhesive, acetone, and toluene, and then dried, thereby allowing surface 1A of alumina board 1 to be coated with a PVB resin to form adhesive layer 61. The mixture solution of acetone and toluene is highly volatile, and thus board 1 dries at room temperature.

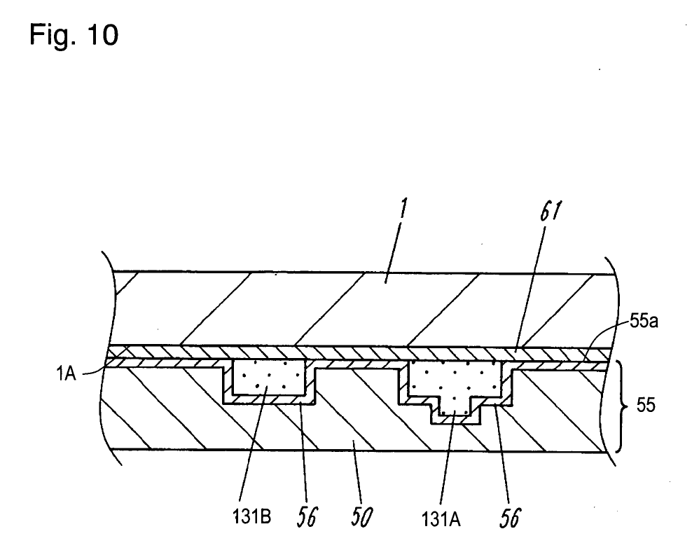

FIG. 10 is a sectional view of intaglio 55 with board 1 placed thereon at Step 36. Surface 55a of intaglio 55 dried at Step 35 is placed on adhesive layer 61 of alumina board 1, is sandwiched between rubbers (not illustrated), is provided with a pressure from the top and bottom of the rubbers, and is heated. The heating causes adhesive layer 61 to melt and penetrate into conductive pastes 131A and 131B, and to be mixed with conductive pastes 131A and 131B.

A heating temperature at Step 39 may be higher than a glass-transition point of the PVB resin, thereby preventing intaglio 55 from being removed from alumina board 1 at adhesive layer 61. The heating temperature may be lower than a temperature at which polymerization degree of adhesive layer 61 is zero prevents defects due to gas, such as vapor caused by broken bonding of molecules in adhesive layer 61. Gas generated in recesses 54 and 154 remains in conductive pastes 131 and 131A since the gas cannot remove away. Adhesive layer 61 is heated at 175° C. for about 20 minutes in the atmospheric ambience to allow the polymerization degree to become zero. According to Embodiment 1, the heating temperature at Step 39 is 140° C. Even at a temperature lower than 175° C., molecular bonding of the PVB resin of adhesive layer 61 is gradually broken, and the gas is accordingly generated. Therefore, the heating temperature is low, 140° C. This provides the conductor patterns with few defects precisely. Then, adhesive layer 61 is cooled to a temperature lower than the glass transition point of the PVB resin of adhesive layer 61, thereby hardening adhesive layer 61 and conductive pastes 131A and 131B, and causing conductive pastes 131A and 131B to be bonded reliably to surface 1A of alumina board 1. Adhesive layer 61 is incompletely hardened at a temperature higher than the glass transition point, and in this condition, may allow intaglio 55 to be removed from alumina board 1 due to vibration caused by handling, such as transferring.

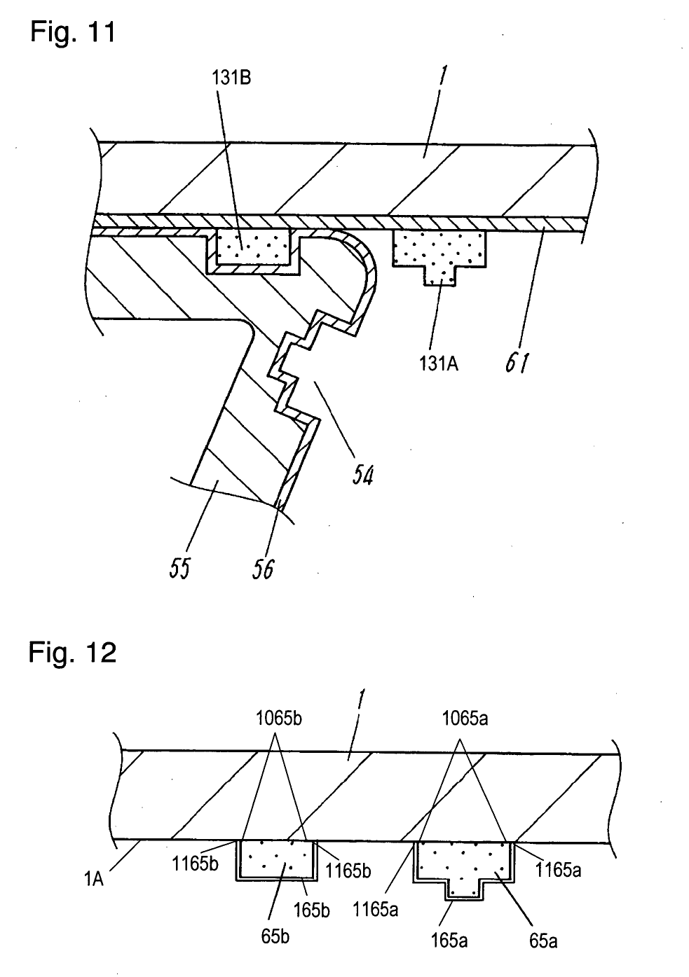

FIG. 11 is a sectional view of board 1 having intaglio 55 being removed at Step 40. Intaglio 55 is removed off from alumina board 1 to transfer conductive pastes 131A and 131B in recesses 54 and 154 onto alumina board 1 to remain there. Recesses 54 and 154 flaring by gradient angle 54a and having releasing layer 56 thereon allow conductive pastes 131A and 131B to be transferred onto surface 1A of alumina board 1 accurately.

Next, at Step 13, as shown in FIG. 12, conductive pastes 131A and 131B on alumina board 1 are baked to sinter silver powder included therein, thus providing conductor patterns 65a and 65b on board 1. At Step 13A, conductive pastes 131A and 131B are baked at a peak temperature of about 850° C. in the atmospheric ambience, an oxidizing atmosphere. This causes conductive pastes 131A and 131B to be fixed onto alumina board 1 due to anchor effect. In other words, according to Embodiment 1, conductor patterns 65a and 65b are formed by transferring with intaglio 55, patterns drawn with recesses 54 and 154 on intaglio 55 are faithfully reproduced, providing accurate conductor patterns 65a and 65b.

According to Embodiment 1, conductive paste 31 contains silver to be baked in the atmospheric ambience, an oxidizing atmosphere, at Step 13A, thus not requiring nitrogen gas. This reduces a cost for the baking at Step 13A, allowing wiring board 60 to be manufactured inexpensively.

At Step 13A, conductive pastes 131A and 131B are baked in the atmospheric ambience, the oxidizing atmosphere, and thus, are oxidized, thus providing an oxide film on the surfaces of conductor patterns 65a and 65b. At Step 22, silver oxide formed on the surfaces of conductor patterns 65a and 65b is cleaned with acid and is removed. At Step 22, silver powder which remains on surface 55a of intaglio 55 and which is transferred to board 1 at Step 32b is also removed, thus preventing short circuit and migration of conductor patterns 65a and 65b.

After this oxide film is removed, a base-plating is applied to the surfaces of conductor patterns 65a and 65b at Step 23. At Step 23, silver in conductor patterns 65a and 65b is replaced by palladium, and palladium plating is applied to conductor patterns 65a and 65b as the base-plating, providing palladium layers 165a and 165b. At Step 23, the plating of replacing silver by palladium selectively provides palladium layers 165a and 165b having about thicknesses of 1 μm on conductor patterns 65a and 65b, respectively. This process prevents palladium from adhering to surface 1A of board 1. Palladium layers 165a and 165b do not extend to surface 1A of board 1. In other words, edges 1165a and 1165b of palladium layers 165a and 165b agree with edges 1065a and 1065b of conductor patterns 65a and 65b, respectively. Therefore, conductor patterns 65a and 65b do not short-circuit due to palladium between the conductor patterns, hence increasing an insulating property of wiring board 60.

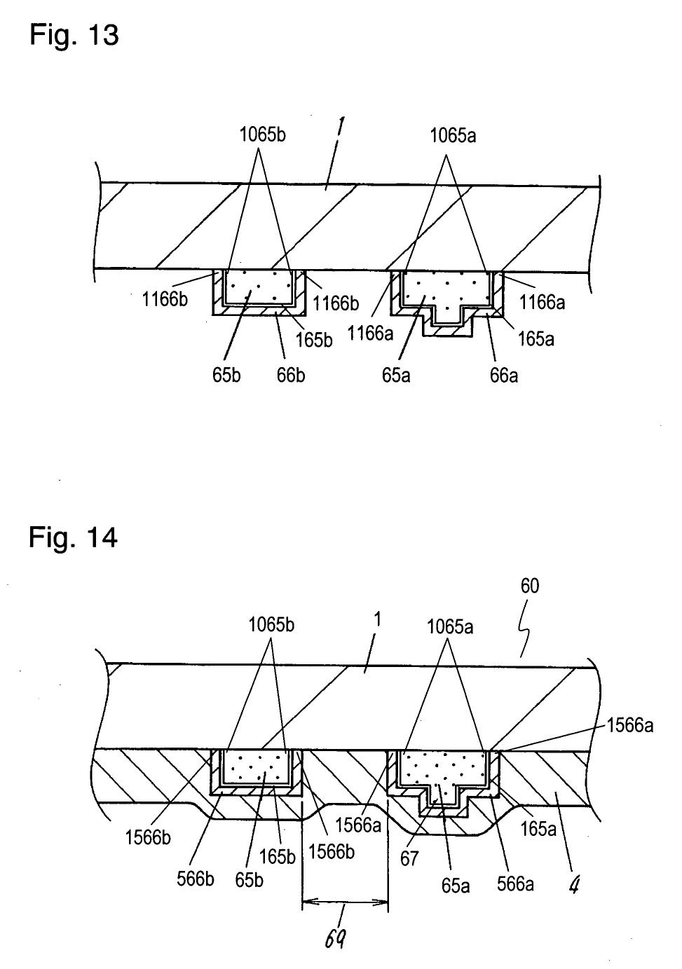

Next, as shown in FIG. 13, electroless nickel plating is performed to palladium layers 165a and 165b to form nickel layers 66a and 66b having a thickness of 3 μm, respectively. Nickel layers 66a and 66b includes about 8 wt % of phosphorus and 92 wt % of nickel. Since nickel layers 66a and 66b are formed by the electroless-plating onto palladium layers 165a and 165b, nickel layers 66a and 66b have uniform thicknesses and are precise with few defects, such as pinholes. This provides highly-reliable wiring board 60. Palladium does not adhere to surface 1A of board 1, and palladium layers 165a and 165b are selectively formed on conductor patterns 65a and 65b. Therefore, nickel layers 66a and 66b are not formed on surface 1A of board 1, but only on palladium layers 165a and 165b. Nickel layers 66a and 66b do not extend to surface 1A of board 1. In other words, edges 1166a and 1166b of nickel layers 66a and 66b agree with edges 1065a and 1065b of conductor patterns 65a and 65b, respectively. However, palladium layers 165a and 165b may not be formed. That is, conductor patterns 65a and 65b may have palladium layers 165a and 165b on the surfaces facing nickel layers 66a and 66b and may not have the palladium layers.

Next, at Step 16, paste 17 made of borosilicate lead glass is printed as to cover nickel layers 66a and 66b. At Step 18, paste 17 is baked at about 850° C. in the atmospheric ambience, the oxidizing atmosphere. The baking oxidizes nickel layers 66a and 66b, thus providing nickel oxide layers 566a and 566b, respectively. Consequently, as shown in FIG. 14, insulating layer 4 is formed on nickel oxide layers 566a and 566b for protecting conductor patterns 65a and 65b electrically and physically. Nickel oxide layers 566a and 566b are not formed on surface 1A of board 1. Nickel oxide layers 566a and 566b do not extend to surface 1A of board 1. In other words, edges 1566a and 1566b of nickel oxide layers 566a and 566b agree with edges 1065a and 1065b of conductor patterns 65a and 65b, respectively. Conductor pattern 65a has projection 67. The above-mentioned processes provide wiring board 60 according to Embodiment 1 shown in FIGS. 14 and 1.

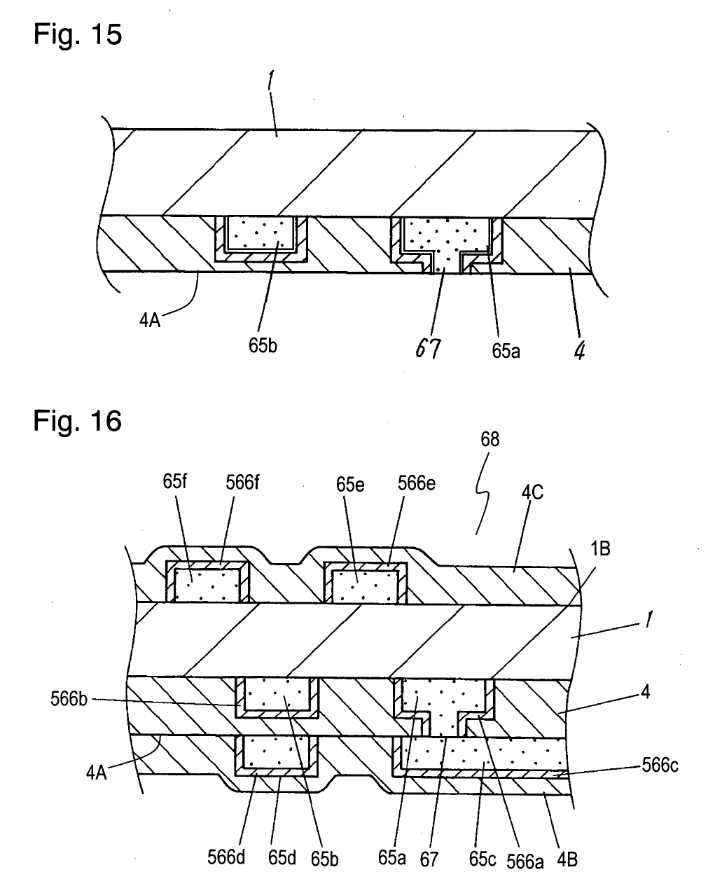

Next, as shown in FIG. 15, surface 4A of insulating layer 4 formed at Step 18 is ground until projection 67 of conductor pattern 65a exposes (Step 19). Then, the processes at and after Step 21 are executed again to form multilayer conductor patterns on alumina board 1.

FIG. 16 is a sectional view of another wiring board 68 according to Embodiment 1 manufactured by processes including Step 19. Conductor patterns 65c and 65d are formed on surface 4A of insulating layer 4, and conductor pattern 65c is connected to projection 67 of conductor pattern 65a to be electrically connected to conductor pattern 65a. Similarly to conductor patterns 65a and 65b, nickel oxide layers 566c and 566d are formed on conductor patterns 65c and 65d, respectively. Insulating layer 4B is formed on nickel oxide layers 566c and 566d and surface 4A of insulating layer 4 similarly to insulating layer 4. The processes at and after Step 21 are executed to form conductor patterns 65e and 65f on lower surface 1B of board 1. Nickel oxide layers 566e and 566f are formed on conductor patterns 65e and 65f, respectively, similarly to conductor patterns 65a and 65b. Insulating layer 4C is formed on nickel oxide layers 566e and 566f and lower surface 1B of board 1 similarly to insulating layer 4.

Conductor pattern 65a is electrically connected to conductor pattern 65c through projection 67. The baking of insulating layer 4 at Step 18 and the baking of conductor patterns 65c and 65d at Step 13 are performed in the atmospheric ambience. Therefore, nickel layers 66a and 66b are oxidized, thus being insulating layers. Consequently, at Step 19, projection 67 is ground until nickel layer 66 on it is completely removed.

In wiring board 68 manufactured by the above-mentioned method, conductor patterns 65a through 65f are covered with nickel oxide layers 566a through 566f including phosphorus oxidized at the baking at Step 18, namely are covered with insulating layers, thus preventing silver migration in conductor patterns 65a through 65f.

According to experiments, it was confirmed that a withstand voltage between conductor patterns 65a and 65b spaced by space 69 of 0.03 mm was higher than about 1000V if the content of phosphorus in the nickel oxide layer was 8 wt %, and the withstand voltage was higher than about 500V if te content was 12 wt %. During this experiments, the withstand voltage was measured after water drops were dropped between conductor patterns 65a and 65b without insulating layer 4 while a direct-current voltage of 1V was applied. As mentioned above, in wiring board 60 according to Embodiment 1, the content of phosphorus in nickel oxide layers 566a through 566f ranging from about 8 wt % to 12 wt % provides a preferable withstand voltage between conductor patterns 65a and 65b.

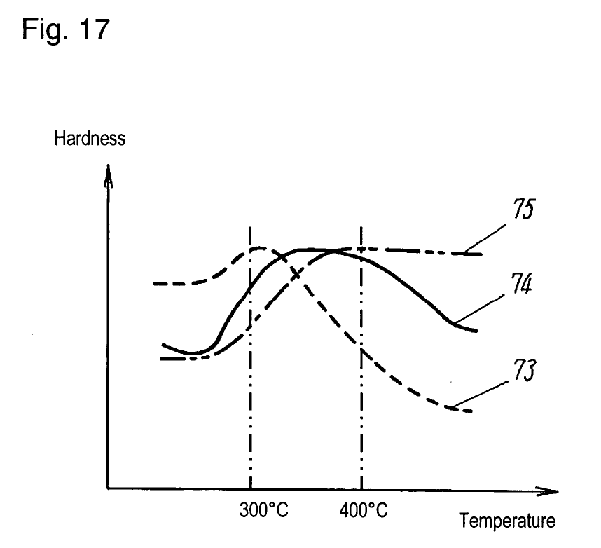

The content of phosphorus in nickel layers 66a and 66b and migration will be described. FIG. 17 illustrates a relationship between a temperature and a hardness of the nickel oxide layer. The horizontal axis represents the temperature, and the vertical axis represents the hardness. Characteristic 73 indicates the hardness of the nickel oxide layer including 1 wt % of phosphorus. Characteristic 74 indicates the hardness of the layer including 8 wt % of phosphorus. Characteristic 75 indicates the hardness of the layer including 12 wt % of phosphorus.

The hardnesses indicated by characteristic 73, 74, and 75 become largest in a temperature range about from 300° C. to 400° C. At temperatures higher than this range, the hardnesses become small. The amount of the decreasing hardness is large particularly for a nickel layer including a small content of phosphorus. It is considered that this phenomenon is caused by the following reason. A nickel layer including the small content of phosphorus has large nickel crystals. The crystals expand and contract largely due to heat, thus producing cracks among the crystals. That is, nickel layers 66a and 66b has their hardness decreasing due to heat and oxidization during the baking. The decreasing of the hardness prevents the nickel oxide layer from standing against intolerable expansion and contraction due to heat, thus causing cracks. The nickel oxide layer accordingly becomes thin partially, and silver may partially expose. Then, the exposing silver is ionized by an applied voltage, and migration occurs.

Therefore, a nickel oxide layer including a large content of phosphorus, prevents the silver migration. According to experiments, it was confirmed that a nickel oxide layer including more than 5 wt % of phosphorus did not produce the silver migration.

However, according to experiments, it was confirmed that a nickel oxide layer including more than 9 wt % of phosphorus sometimes produced the silver migration. In order to confirm this, a PCTB test was performed for nickel layers including 8 wt % and 12 wt % of phosphorus at an ambient temperature of 121° C., at an ambience humidity of 99%, at a pressure of 2 atmospheres, and an applied direct-current voltage of 3.3V. Then, occurrence rate of short circuit between conductor patterns 65a and 65b was measured.

As a result, a conductor pattern including a nickel layer including 8 wt % of phosphorus does not exhibit a short circuit even after 100 hours have elapsed. A conductor pattern including a nickel layer including 12 wt % of phosphorus exhibits a short circuit at the rate of about 18%. This results from insulating layer 4 made of borosilicate lead glass. That is, phosphorus included in the nickel layer diffuses into the borosilicate lead glass, thus decreasing the insulating resistance of insulating layer 4. According to Embodiment 1, if insulating layer 4 is made of material into which phosphorus tends to diffuse, such as glass-based material including borosilicate lead glass, the content of phosphorus in the nickel layer ranges between 5 wt % and 9 wt % avoid the migration most.

As mentioned above, the content of phosphorus in nickel layers 66a and 66b ranges between about 5 wt % and 12 wt %, and the deterioration of the hardness of nickel oxide layers 566a and 566b is reduced. This accordingly prevents migration between conductor patterns 65a and 65b, thus assuring preferable insulating property between conductor patterns 65a and 65b. It is important to determine the content of phosphorus so that the insulation of insulating layer 4 does not deteriorate due to the diffusion of the phosphorus into insulating layer 4.

According to Embodiment 1, the content of phosphorus in nickel layers 66a and 66b is determined to range between about 5 wt % and 12 wt %, and prevents migration even if nickel layers 66a and 66b are oxidized due to the baking. Therefore, insulating paste 17 for providing insulating layer 66 can be baked in the atmospheric ambience, and does not require expensive inactive gas, such as nitrogen, thus reducing running costs in its manufacturing process.

Further, nickel layer 66 including 5 wt % to 12 wt % of phosphorus prevents migration, hence allowing a voltage to be applied between the conductor patterns. This is useful for a device, such as a balun, a transformer for balanced/unbalanced conversion, inserted between an amplifier and a filter of a high-frequency apparatus.

If the content of phosphorus ranges particularly between 5 wt % and 9 wt %, migration is prevented even if insulating layer 4 is made of borosilicate lead glass, into which phosphorus tends to diffuse, hence allowing a higher voltage to be applied to conductor patterns.

The nickel layers according to Embodiment 1 are formed by the electroless-plating, and thus, do not produce defects, such as pinholes. Therefore, the migration can be reliably prevented even if nickel layer 66 is thin. Further, conductor pattern 65 has accurate dimensions, and the nickel layers are formed easily.

Nickel layers 66a and 66b prevents the migration, and allowing space 69 between conductor patterns 65a and 65b adjacent to each other to decrease. Although space 69 according to Embodiment 1 is 0.15 mm, the migration between conductor patterns 65a and 65b does not occur. Therefore, a large number of conductor patterns can be arranged in wiring boards 60 and 68 at high density.

### Exemplary Embodiment 2

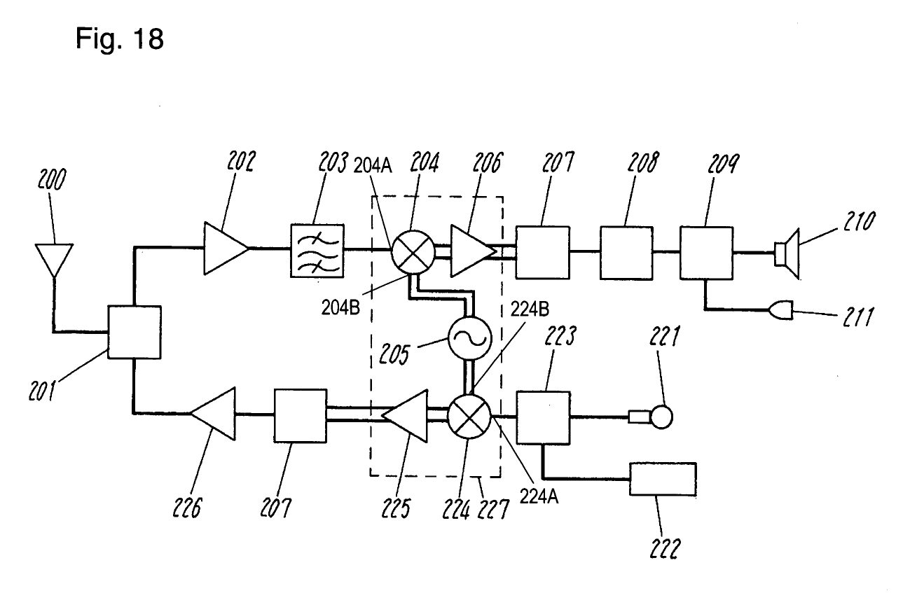

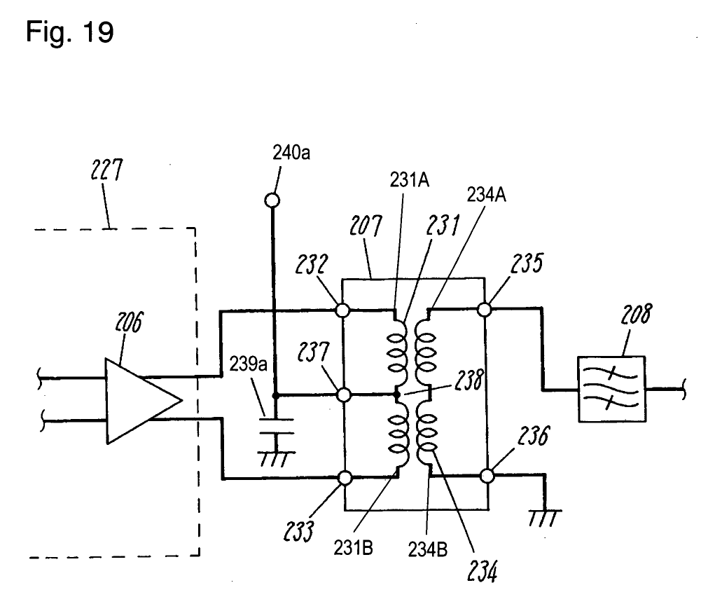

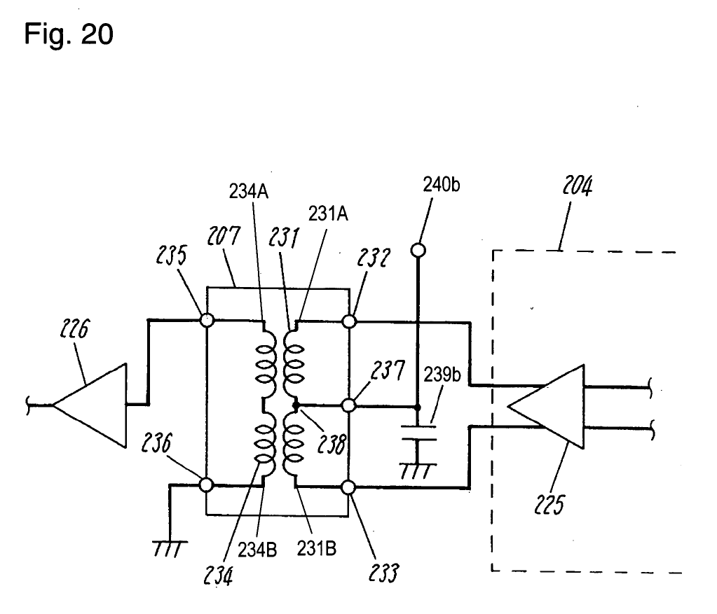

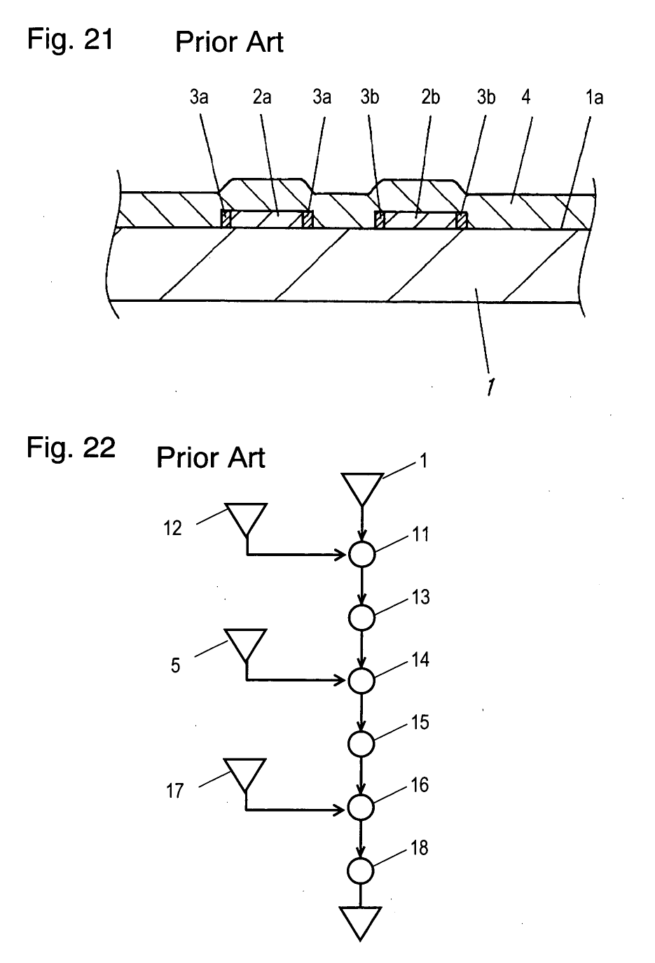

FIG. 18 is a block diagram of a portable phone, an apparatus according to Exemplary Embodiment 2 of the present invention. FIG. 19 is a circuit diagram of a balun in a receiving system of the portable phone shown in FIG. 18, and FIG. 20 is a circuit diagram of a balun in a transmitting system of the phone.

First, the receiving system will be described. Antenna 200 having a length of about 40 mm sends and receives high-frequency signals of about 800 MHz. Antenna 200 is connected to input/output port 201a of diplexer 201, and an output port of diplexer 201 is connected to low-noise amplifier (LNA) 202. An output of low-noise amplifier 202 is supplied to filter 203. Mixer 204 having input ports 204A and 204B mixes an output of filter 203 supplied to input port 204A and an oscillation signal from local oscillator 205 supplied to input port 204B, and converts a high-frequency signal output from filter 203 into an intermediate-frequency signal having a low frequency output as balanced signals. Differential amplifier 206 amplifies an output from mixer 204 and output balanced signals. Balun 207 converts the balanced signals output from amplifier 206 into an unbalanced signal. Balun 207 is connected to the collector of an output-stage transistor in differential amplifier 206, and a voltage is applied to the collector of an output-stage transistor in amplifier 206 through balun 207. Unbalanced intermediate-frequency filter 208 connected to output ports of balun 207 allows only intermediate-frequency signals to pass through it. According to Embodiment 2, intermediate-frequency filter 208 employs a SAW filter. Signal processor 209 processes signals output from intermediate-frequency filter 209 to output the processed signal to an output device, such as loudspeaker 210 and liquid crystal indicator 211.

Next, the transmitting system will be described. An output from an input device, such as microphone 221 and keyboard 222, is input to signal processor 223. Mixer 224 having input ports 224A and 224B mixes a signal from processor 223 supplied to input port 224A and an oscillation signal from local oscillator 205 supplied to input port 224B and converts a signal from signal processor 223 into balanced high-frequency signals of about 800 MHz. Amplifier 225 amplifies the signals from mixer 224 to output balanced signals. Both amplifier 225 and mixer 224 are composed of balanced circuits. The balanced signals output from amplifier 225 are converted into an unbalanced signal by balun 207, and supplied to power amplifier 226. A signal output from power amplifier 226 is supplied to antenna 200 through diplexer 201 and emitted.

According to Embodiment 2, mixers 204 and 224, local oscillator 205, and amplifiers 206 and 225 are integrated to integrated circuit 227. Further, mixers 204 and 224, local oscillator 205, and amplifiers 206 and 225 are composed of balanced circuits, which immune to interference. Therefore, these circuits are resistant to interference one another even located closely to each other, and thus, provides integrated circuit 37 having a small size, hence providing a small portable phone.

FIG. 19 is a circuit diagram of the balun used in the receiving system of the portable phone shown in FIG. 18. Conductor pattern 231 forming an inductor has terminal 232 provided at one end 231A of the pattern, and has terminal 233 on other end 231B of the pattern. Conductor pattern 234 forming an inductor electromagnetically is coupled to with conductor pattern 231. Conductor patterns 231 and 234 are arranged on an alumina board in parallel with each other by a space of about 0.15 mm between them. Terminal 235 provided at one end 234A of conductor pattern 234 is connected to intermediate-frequency filter 208. Terminal 236 provided at other end 234B of conductor pattern 234 is connected to a ground. Ground terminal 237 is connected to center tap 238 of conductor pattern 231 and to power supply terminal 240a. Ground terminal 237 is connected to the ground through capacitor 239a. A direct-current voltage is applied to power supply terminal 240a for driving amplifier 206. This direct-current voltage is supplied to amplifier 206 through conductor pattern 234 of balun 207, hence eliminating a large choke coil for supplying a direct current power to amplifier 206, thus providing a small portable phone.

Balun 207 is formed of the wiring board shown in FIG. 1 or 14 according to Embodiment 1. That is, each of conductor patterns 231 and 234 is formed with conductor pattern 65a and nickel oxide layer 566a provided on alumina board 1. The nickel oxide layer includes about 8 wt % of phosphorus. Insulating layer 4 made of glass-based material is provided on nickel oxide layer 566a. Even if a voltage to be supplied to amplifier 206 is applied to conductor pattern 234, silver migration does not occur between conductor patterns 231 and 234. This provides a highly-reliable balun having high-frequency characteristics not changing for a long period of time, thus providing a highly-reliable apparatus, a portable phone.

FIG. 20 is a circuit diagram of balun 207 used for the transmitting system of the portable phone according to Embodiment 2. In FIG. 20, the same components as in FIG. 19 are denoted the same reference numerals, and their description is simplified. The outputs from amplifier 225 are connected to terminals 232 and 233. Terminal 235 is arranged to be connected to power amplifier 226. A direct-current voltage is supplied to power supply terminal 240b for driving amplifier 225. This direct-current voltage is supplied to amplifier 225 through conductor pattern 234 of balun 207. Similarly to the receiving system, a power is supplied to amplifier 225 through balun 207. Therefore, a large choke coil for supplying a direct-current power to amplifier 225 is not required, thus providing a small portable phone.

Migration is not occur between conductor patterns 231 and 234 of balun 207 in the transmitting system, similarly to that in the receiving system. This provides the highly-reliable balun having high-frequency characteristics not changing for a long period of time, thus providing a highly-reliable portable phone.

The transmitting system requires a large power and amplifier 225 and power amplifier 226 have large gains. Therefore, a large current is supplied to amplifier 225. Migration is not occur between conductor patterns 231 and 234 of balun 207 according to Embodiment 2, and thus, the balun is useful particularly for the transmitting system.

In balun 207 according to Embodiment 2, the nickel oxide layer including phosphorus is provided on conductor pattern 231 to which direct-current power is applied, and the nickel oxide layer on conductor pattern 234 may not be provided, thereby providing similar effects. That is, the nickel oxide layer containing phosphorus may be provided on at least one of the conductor patterns adjacent to each other, thereby providing similar effects.

According to Embodiment 2, balun 207 is described, however, the wiring board according to Embodiment 1 may be applied to other electronic components to which a direct-current voltage is applied, thus being effective similarly to balun 207.

Migration does not occur between conductor patterns 231 and 234 since conductor patterns 231 and 234 include about 8 wt % of phosphorus. A space between conductor patterns 231 and 234 may be accordingly reduced to a short distance of 0.15 mm, accordingly increasing a coupling factor between conductor patterns 231 and 234, and decreasing a loss due to electromagnetic coupling in balun 207. The alumina board, having a large dielectric constant, shortens the space between conductor patterns 231 and 234, and hence reduces the size of balun 207. Therefore, the wiring board according to Embodiment 1 reduces the size of the apparatus according to Embodiment 1, hence being useful particularly for a portable apparatus, such as a portable phone.

1. A wiring board comprising:
an insulating inorganic base;
a conductor pattern provided on the base and including silver;
a nickel oxide layer provided on the conductor pattern and covering the conductor pattern, the conductor pattern including 5 wt % to 12 wt % of phosphorus; and
an insulating layer provided on the nickel oxide layer.

2. The wiring board as defined in claim 1,
wherein the insulating layer is made of a glass-based material, and
wherein the nickel oxide layer includes 5 wt % to 12 wt % of phosphorus.

3. The wiring board as defined in claim 1, wherein the conductor pattern includes a palladium layer provided on a surface thereof facing the nickel oxide layer.

4. The wiring board as defined in claim 1, wherein the conductor pattern having and edge agreeing with an edge of the nickel oxide layer.

5. A balun comprising:
an insulating inorganic board;
a first conductor pattern provided on the board and including silver, the first conductor pattern forming a first inductor having a first end, a second end, and a center tap;
a first nickel oxide layer including 5 wt % to 12 wt % of phosphorus provided on the first conductor pattern, the first nickel oxide layer covering the first conductor pattern;
a second conductor pattern provided on the board and including silver, the second conductor pattern forming a second inductor electromagnetically coupling with the first inductor and having a first end and a second end;
a first terminal connected to the first end of the first inductor;
a second terminal connected to the second end of the first inductor;
a third terminal connected to the first end of the second inductor;
a fourth terminal connected to the second end of the second inductor;
a fifth terminal connected to the center tap of the first inductor, a direct-current voltage is supplied to the fifth terminal.

6. The balun as defined in claim 5, further comprising an insulating layer made of glass-based material provided on the first nickel oxide layer and the second conductor pattern, wherein the first nickel oxide layer includes 5 wt % to 9 wt % of phosphorus.

7. The balun as defined in claim 5, further comprising a second nickel oxide layer including 5 wt % to 12 wt % of phosphorus provided on the second conductor pattern, the second nickel oxide layer covering the second conductor pattern.

8. The balun as defined in claim 5, further comprising an insulating layer made of glass-based material provided on the first nickel oxide layer and the second nickel oxide layer, wherein the first nickel oxide layer and the second nickel oxide layer include 5 wt % to 9 wt % of phosphorus.

9. The balun as defined in claim 5, wherein the fifth terminal is connected to a ground through a capacitor.

10. An apparatus comprising:
a high-frequency filter to which a high-frequency signal input to an antenna is supplied;
a local oscillator;
a mixer mixing an output from the high-frequency filter and an output from the local oscillator and outputting balanced signals;
a balun including
an insulating inorganic board,
a first conductor pattern provided on the board and including silver, the first conductor pattern forming a first inductor having a first end, a second end, and a center tap, the first end and the second end of the first inductor receiving the balanced signals output from the mixer, the center tap of the first inductor receiving a direct-current voltage, the direct-current voltage being output through the first end and the second end of the first inductor,
a first nickel oxide layer including 5 wt % to 12 wt % of phosphorus provided on the first conductor pattern, the first nickel oxide layer covering the first conductor pattern;
a second conductor pattern provided on the board, the second conductor pattern forming a second inductor electromagnetically coupling with the first inductor and having a first end and a second end;
a capacitor connected between a ground and the center tap of the first inductor of the balun; and
an output device to which a signal output from the first end of the second inductor of the balun is supplied.

11. An apparatus comprising:
an input device;
a local oscillator;
a mixer mixing an output from the input device and an output from the local oscillator, and outputting balanced signals;
a balun including
an insulating inorganic board,
a first conductor pattern provided on the board and including silver, the first conductor pattern forming a first inductor having a first end, a second end, and a center tap, the first end and the second end of the first inductor receiving the balanced signals output from the mixer, the center tap of the of the first inductor receiving a direct-current voltage, the direct-current voltage being output through the first end and the second end of the first inductor,
a first nickel oxide layer including 5 wt % to 12 wt % of phosphorus provided on the first conductor pattern, the first nickel oxide layer covering the first conductor pattern;
a second conductor pattern provided on the board, the second conductor pattern forming a second inductor electromagnetically coupling with the first inductor and having a first end and a second end;
a capacitor connected between a ground and the center tap of the first inductor of the balun; and
a power amplifier amplifying an output from the first end of the second inductor of the balun and supplying the amplified output to an antenna.

12. A method of manufacturing a wiring board, comprising:
providing an insulating inorganic board;
forming a conductor pattern including silver on the board;
forming a nickel oxide layer covering the conductor pattern, the nickel oxide layer including 5 wt % to 12 wt % of and; and
forming an insulating layer on the nickel oxide layer, the insulating layer covering the nickel oxide layer.

13. The method as defined in claim 12, wherein said forming of the nickel oxide layer comprises forming the nickel oxide layer having an edge of the conductor pattern agreeing with an edge of the nickel oxide layer.

14. The method as defined in claim 12, wherein said forming of the nickel oxide layer comprises:
forming a nickel layer covering the conductor pattern; and
oxidizing the nickel layer.

15. The method as defined in claim 14, wherein said forming of the nickel layer comprises forming the nickel layer covering the conductor pattern by electroless plating.

16. The method as defined in claim 14,
wherein the nickel oxide layer includes 5 wt % to 9 wt % of phosphorus, and
wherein said forming of the insulating layer comprises:
applying a glass-based insulating paste on the nickel layer; and
baking the applied insulating paste.

17. The method as defined in claim 12, further comprising
forming a palladium layer on the conductor pattern,
wherein said forming of the nickel oxide layer comprises forming the nickel oxide layer on the palladium layer.

18. The method as defined in claim 17, wherein said forming of the palladium layer comprises replacing silver included in the conductor pattern by palladium.

19. The method as defined in claim 12, wherein said forming of the conductor pattern comprises:
providing an intaglio made of a flexible film, the intaglio having a surface having a recess provided therein;
filling the recess of the intaglio with a conductive paste including silver;
drying the conductive paste;
placing the surface of the intaglio having the recess thereon filled with the conductive paste onto the board;
heating and pressurizing the placed intaglio and the board;
removing the intaglio off from the board to transfer the conductive paste onto the board after said heating and pressurizing of the placed intaglio and the board; and
baking the transferred conductive paste to provide a conductor pattern.

20. The method as defined in claim 19, further comprising baking the conductor pattern in an oxidizing atmosphere.

21. The method as defined in claim 20,
wherein said baking of the conductor pattern comprises baking the conductor pattern so that an oxide film is formed on the conductor pattern,
wherein said filling of the recess with the conductive paste comprises:
applying a conductive paste on the surface of the intaglio to fill the recess with the applied conductive paste;
removing an unnecessary conductive paste on the surface of the intaglio other than the conductive paste filling the recess out of the applied conductive paste so that silver remains on the surface of the intaglio, and
wherein said removing the intaglio off from the board to transfer the conductive paste onto the board comprises removing the intaglio off the board to transfer the conductive paste onto the board, so that the remaining silver is transferred onto the board,
said method further comprising removing the transferred silver and the oxide film formed on the conductor pattern.

22. The method as defined in claim 21, wherein said removing of the unnecessary conductive paste on the surface of the intaglio comprises scraping the unnecessary conductive paste from the surface of the intaglio with a squeegee.

23. The method as defined in claim 19,
wherein said providing the board comprises providing the board having an adhesive layer on a surface thereof, and
wherein said placing of the surface of the intaglio onto the board comprises placing the surface of the intaglio having the recess filled with the conductive paste onto the adhesive layer.
